(19) United States
(12) Patent Application Publication
(10) Pub. No.: US 2023/0290791 A1
(43) Pub. Date: Sep. 14, 2023

(54) IMAGING DEVICE

(71) Applicant: Rosnes Corporation, Kyoto (JP)

(72) Inventors: Takumi YAMAGUCHI, Kyoto (JP); Kenichi SHIMOMURA, Kyoto (JP); Shiro DEGUCHI, Kyoto (JP)

(21) Appl. No.: 18/040,757

(22) PCT Filed: Aug. 5, 2021
(86) PCT No.: PCT/JP2021/029148

§ 371 Date: Feb. 6, 2023

(30) Foreign Application Priority Data
Aug. 7, 2020 (JP) 2020-135078

(51) Int. Cl. H01L 27/146

(52) U.S. Cl. CPC H01L 27/14607

(57) ABSTRACT

There are provided an imaging device and an electronic device that minimize an ineffective region inside a pixel and achieve reduction in size, high SN, high sensitivity, high resolution, and a reduced afterimage.

### TECHNICAL FIELD

The present invention relates to an imaging device, and, in particular, to an imaging device in which a plurality of pixels having a plurality of signal holding units are arranged, or an electronic apparatus including the imaging device.

### BACKGROUND ART

In recent years, the mainstream of imaging devices used for cameras is shifting from a CCD to a CMOS image sensor. A conventional CCD has a feature in which a field sequential reading system that can simultaneously read out charge of a light receiving unit to a vertical CCD in a pixel can be realized for all pixels, and image distortion does not occur at the time of imaging a high-speed subject.

On the other hand, in a CMOS image sensor for a mobile phone or the like, since high pixels are required, pixels with a simple configuration by which downsizing can be realized are employed, and a line sequential reading system that reads out charge of a light receiving unit for each row is the mainstream. In the line sequential reading system, there is a disadvantage that image distortion occurs when a high-speed subject is imaged.

FIG. 13 is a diagram of a pixel of a conventional general CMOS image sensor. In order to downsize a pixel 1, the pixel 1 has a simple structure including only a light receiving unit 2 and an output unit 3 of a photodiode (PD). As illustrated in FIG. 13, a shape indicating a boundary region of the pixel 1 is generally a square, and in the case of FIG. 13, the vertical pixel dimension and the horizontal pixel dimension are the same.

FIG. 14 is an arrangement diagram of a CMOS image sensor in which conventional quadrangular pixels are arranged vertically and horizontally.

The pixels 1 are arranged in a matrix in a vertical axis (V) direction and a horizontal axis (H) direction at a pitch of the vertical dimension of the pixels and a pitch of the horizontal dimension of the pixels, respectively.

A signal due to charge of the light receiving unit 2 of the pixel 1 in each column (Y, Y+1, Y+2, Y+3) in a row X is read out from the output unit 3 of each pixel to the outside of the CMOS sensor through a vertical signal line 4. Similarly, signals of pixels in each row are read in the order of X+1, X+2, and X+3.

A system of reading out in the order of rows of X, X+1, X+2, and X+3 is called a line sequential reading system.

FIG. 14 illustrates the case where a boundary region of pixels is a square pixel. However, even when the boundary region of the pixels is a rectangle, a rhombus, a trapezoid, or a curve, the same applies to a case where the pixels are arranged in a matrix with the pitch of the vertical dimension of the pixels and the pitch of the horizontal dimension of the pixels in the vertical axis (V) direction and the horizontal axis (H) direction, respectively.

FIG. 15 is a circuit diagram of a pixel of a line sequential reading system. By applying positive voltage to a transfer transistor wiring 6 of a transfer unit 5, a transfer transistor is turned on, and charge Q1 of the light receiving unit 2 is read out to the floating diffusion unit 7 (FD 7) of the output unit 3.

The transfer transistor wiring 6 in a pixel is common in each row illustrated in FIG. 14, and the charge Q1 of the light receiving unit 2 corresponding to each pixel in each row is simultaneously read out to the FD 7 by the read-out operation. The charge Q1 of the light receiving unit 2 transferred to the FD 7 is converted into voltage V=(Q1÷C1) by capacitance C1 of the FD 7.

After the above, in a state where a pixel power supply 10 is positive voltage, positive voltage is applied to a row selection electrode wiring 13, so that a row selection transistor 12 is turned on, and the voltage V=(Q1÷C1) of the FD 7 is read out as signal voltage from the vertical signal line 4 through an output transistor 11.

Furthermore, as positive voltage is applied to a reset transistor wiring 9, a reset transistor 8 is turned on, and the voltage V of the FD 7 is reset. By such a series of driving, the read-out operation of a pixel ends.

Here, the vertical signal line 4 in FIG. 15 is common to pixels in rows X, X+1, X+2, and X+3 in column Y in FIG. 14. Further, the row selection transistor wiring 13 in FIG. 15 is common to pixels in columns Y, Y+1, Y+2, and Y+3 in column X in FIG. 14.

In the line sequential reading system, in a case of a system of reading out an upper row of a screen first and sequentially reading lower rows, a difference in reading time is generated between row X and row X+3 in FIG. 14. For this reason, it is widely known that there is a disadvantage that an image is distorted when a high-speed subject is imaged.

FIG. 16 illustrates a cross-sectional structure of a semiconductor of a pixel of a CMOS image sensor. The charge Q1 generated in the light receiving unit 2 is held by an N-type semiconductor of the light receiving unit 2 formed in a semiconductor substrate 14. The reason why the light receiving unit 2 is an N-type semiconductor is that when positive voltage is applied to the transfer transistor wiring 6 and a transfer transistor of the transfer unit 5 is turned on, an N-type semiconductor region of the light receiving unit 2 is completely depleted, and all of the charges Q1 of the light receiving unit 2 are completely transferred to the FD 7.

By the above, the remaining charge Q1 is not generated in the light receiving unit 2, and thus, it is possible to eliminate charge that becomes an afterimage of the light receiving unit 2.

A portion of a P type semiconductor on a semiconductor surface of the light receiving unit 2 plays a role of suppressing leakage charge generated from a defect on the semiconductor surface, and a structure in which a P type semiconductor is generated on a semiconductor surface of an upper layer portion of the N-type semiconductor of the light receiving unit 2 is called an embedded photodiode, and is a structure employed in most products in general-purpose CMOS image sensors.

As described above, in a conventional CMOS image sensor, the line sequential reading system of reading charge of the light receiving unit for each row is mainly performed using the structure of FIGS. 14, 15, and 16.

On the other hand, there is a method of realizing a field sequential reading system similar to that of a CCD by changing a driving method using the structure of FIGS. 14, 15, and 16. This system is called a floating diffusion (FD) holding type global shutter system. This system has a feature that image distortion does not occur at the time of imaging a high-speed subject, but has a disadvantage that it is difficult to put the system into practical use since leakage charge of an FD is added to the charge Q1 of the light receiving unit 2 and becomes noise.

By using this system, in all the pixels 1 in FIG. 14, positive voltage is simultaneously applied to the transfer transistor wiring 6 of the transfer unit 5 in FIG. 15, the charge Q1 of all the light receiving units 2 can be read out to the FD 7 in the output unit 3 of each pixel at the same time. Therefore, for a high-speed subject, charge of the light receiving units 2 of all the pixels can be transferred to the output unit 3 at the same time.

After the above, as illustrated in FIG. 14, by turning on the row selection transistor 12 of each pixel of row X, charge in the FD 7 of the output unit 3 in a pixel of row X is converted into voltage via the output transistor 11 and read out as a signal from the vertical signal line 4. Similarly to row X, signal voltage can be read out from a CMOS image sensor in the order of rows X+1, X+2, and X+3.

By using this driving method, charge of each of the pixels 1 of a CMOS image sensor is simultaneously read out to the output unit 3, so that the same operation as in a case where charge of each pixel of a CCD is read out to a vertical CCD can be realized, and image distortion does not occur.

However, when a time at which charge of the FD 7 of the output unit 3 of row X is converted into voltage and read out is Z0, a time Z3 at which charge of the FD 7 of the output unit 3 of row X+3 is converted into voltage and read out is a later time.

Assuming that a time at a moment when charge of the light receiving units 2 of all the pixels is read out to the FD 7 in the output unit 3 of each pixel is Z, time during which charge of the light receiving unit 2 is held in the FD 7 is (Z0−Z) in row X.

Further, in row X+3, time during which charge of the light receiving unit 2 is held in the FD 7 is (Z3−Z), and between row X and row X+3, time during which charge of the light receiving unit 2 is held in the FD 7 is different.

In FIG. 16, the FD 7 is a semiconductor of an N+ type semiconductor having a high N type impurity concentration, and the reason for that is to realize ohmic contact for connecting a semiconductor of the FD 7 and a metal wiring directed to the output transistor 11 without any failure. This is an N+ type semiconductor because the source and the drain of a general N type MOS transistor are connected to a metal wiring, and has a similar structure.

In a region of an N+ type semiconductor, since a silicon (Si) semiconductor contains a large amount of N type impurities such as arsenic (As) having an atomic radius different from that of Si, distortion due to a difference in atomic radius between Si and As occurs inside a Si semiconductor, and many defects occur in the Si semiconductor. At this time, in a region of an N+ type semiconductor of the FD 7, leakage charge generated from a defective portion is mixed in signal charge read out from the light receiving unit 2. An amount of leakage charge mixed increases in proportion as time during which signal charge read out from the light receiving unit 2 is held in the FD 7 becomes longer.

Therefore, time (Z3−Z) of row X+3 in which charge of the light receiving unit 2 is held in the FD 7 is considerably longer than (Z0−Z) of row X, and noise charge due to leakage charge of row X+3 becomes extremely large. For example, when read time of one frame of the CMOS image sensor in FIG. 14 is 1/30 seconds, a difference between time (Z0−Z) in a first row X and time (Z3−Z) in a last row X+3 is long time obtained by subtracting a vertical blanking period from 1/30 seconds of one frame time.

Therefore, since the leakage charge is proportional to time, in the FD 7 of a pixel of row X+3, a considerably large amount of leakage charge is mixed into the charge Q1 of the light receiving unit 2, and signal to noise (SN) indicating a ratio between signal charge S (Signal) of the light receiving unit 2 and noise charge N (Noise) due to the leakage charge is considerably deteriorated.

For this reason, in an image of the CMOS image sensor, SN of pixels is poor in rows X, X+1, X+2, and X+3 in this order, and image quality deterioration strongly occurs in a lower region of the image.

As described above, in a case where the CMOS image sensor of the line sequential reading system is used and used with a field sequential reading system similar to a CCD, SN is poor due to influence of noise, and such use is not put into practical use.

In recent years, a CMOS image sensor of a global shutter system that realizes a field sequential reading system replacing a CCD has been commercialized.

A pixel in the global shutter system includes two types: a charge holding type that holds the charge Q1 transferred from the light receiving unit 2; and a voltage holding type that converts the charge Q1 transferred from the light receiving unit 2 into voltage in a pixel and holds the voltage.

In a case of the charge holding type, an area of capacitance for holding charge is required, and in a case of the voltage holding type, a circuit using a large number of transistors is required in order to convert charge into voltage. In general, in order to realize downsizing of the pixel 1, the charge holding type in which a region for holding a signal from the light receiving unit 2 is relatively small is often employed.

FIG. 17 is a diagram of a pixel of a CMOS image sensor of a conventional charge holding type global shutter system. In the pixel 1 of the global shutter system, a signal holding unit 15 is provided between the light receiving unit 2 and the output unit 3.

FIG. 18 is an arrangement diagram of a CMOS image sensor in which pixels of a charge holding type global shutter system are vertically and horizontally arranged. In the global shutter system, the charge Q1 of the light receiving unit 2 is simultaneously transferred to the signal holding unit 15 at the same time in all the pixels. After the above, charge of the signal holding unit 15 in each row of X, X+1, X+2, and X+3 is read out from the CMOS image sensor for each row in the order of X, X+1, X+2, and X+3 via the output unit 3 and the vertical signal line 4.

FIG. 19 is a circuit diagram of a pixel of a CMOS image sensor of a charge holding type global shutter system. In the pixel, a capacitance C2 to be the signal holding unit 15 is arranged between the light receiving unit 2 and the output unit 3. In all the pixels, positive voltage is applied to the transfer transistor wiring 6, and as a transfer transistor of the transfer unit 5 is turned on, the charge Q1 of the light receiving unit 2 is transferred to the capacitance C2 of the signal holding unit 15 at the same time.

After the above, when positive voltage is applied to a reading transistor wiring 17 of a reading unit 16 and a reading transistor of the reading unit 16 is turned on, the charge Q1 held in the signal holding unit 15 is transferred to the FD 7 and transmitted to the output transistor 11 as voltage V=Q1÷C1.

In recent years, a CMOS image sensor including a plurality of the signal holding units 15 has been proposed using the principle of the global shutter system. With this structure, it is possible to realize a global shutter type CMOS image sensor capable of reading out a signal for a plurality of frames from the signal holding unit 15 in a pixel at high speed. Further, this structure is also used as a CMOS image sensor for time of flight (ToF) for measuring a distance.

FIG. 20 is a cross-sectional structure diagram of a pixel having a structure of a signal holding unit using an N+ type semiconductor. The capacitance C2 of the signal holding unit 15 uses an N+ type semiconductor to have large capacitance so that the charge Q1 of the light receiving unit 2 can be sufficiently held, and is larger than the capacitance C1 of the FD 7. When a transistor of the transfer unit 5 is turned on, the charge Q1 of the light receiving unit 2 is . . . to the signal holding unit 15 of the N+ type semiconductor.

FIG. 21 is a cross-sectional structure diagram of a pixel having a structure of a signal holding unit using metal-insulator-metal (MIM) capacitance.

This is MIM capacitance in which an insulating layer Insulator (I) is formed between metal Metal (M-1) and metal Metal (M-2).

In the MIM capacitance, the M-1 side is an electrode for holding charge of the light receiving unit 2, and the M-2 side is zero voltage (GND). When a transistor of the transfer unit 5 is turned on, the charge Q1 of the light receiving unit 2 is transferred to an N+ type semiconductor of the MIM capacitance in contact with the transfer unit 5, and then held by M-1 via a wiring.

In FIGS. 20 and 21, when the charge Q1 of the light receiving unit 2 is transferred to the signal holding unit 15 as a transfer transistor of the transfer unit 5 is turned on, the charge Q1 is converted into voltage [V2=Q1÷C2] of the signal holding unit 15.

Next, when a reading transistor of the reading unit 16 is turned on, the signal holding unit 15 and the FD 7 are connected, and the total capacitance becomes C1+C2, so that the voltage V1 of the FD 7 is expressed as follows:

$$\begin{matrix}V 1 = C 2 \div ( C 1 + C 2 ) \times V 2 \\ = C 2 \div ( C 1 + C 2 ) \times ( Q 1 \div C 2 ) \\ = Q 1 \div ( C 1 + C 2 ) .\end{matrix}$$

On the other hand, in the CMOS image sensor of a general line sequential reading system as illustrated in FIG. 16, voltage of the FD 7 is [V1=Q1/C1], and all the charges Q1 of the light receiving unit 2 can be directly detected by the FD 7. Therefore, the structure of the signal holding unit 15 using the N+ type semiconductor in FIG. 20 and the structure of the signal holding unit 15 using the MIM capacitance in FIG. 21 have a problem that conversion efficiency of voltage transmitting the charge Q1 of the light receiving unit 2 to the output unit 3 via the signal holding unit 15 is poor.

Further, the structure of the signal holding unit 15 using the N+ type semiconductor of FIG. 20 and the structure of the signal holding unit 15 using the MIM capacitance of FIG. 21 both have an N+ type semiconductor region inside the signal holding unit 15 similarly to the FD 7, and thus, there is a problem that leakage charge generated in the N+ type semiconductor region of the signal holding unit 15 is mixed into the charge Q1 of the light receiving unit 2, and SN is poor.

FIG. 22 is a cross-sectional structure diagram of a pixel having a structure of a signal holding unit using MOS type capacitance.

The structure of FIG. 22 is designed such that after all the charges Q1 of the light receiving unit 2 are held in the signal holding unit 15, all the charges Q1 of the light receiving unit 2 are completely transferred from the signal holding unit 15 to the FD 7.

The MOS type capacitance of the signal holding unit 15 has a configuration in which an N-type semiconductor is arranged under an electrode 18 of the MOS type capacitance. In FIG. 22, since an N-type semiconductor is used for the signal holding unit 15 and an amount of N type impurities is small, leakage charge caused by the N type impurities can be reduced. For this reason, as illustrated in FIGS. 20 and 21, SN can be improved as compared with a case where an N+ type semiconductor is used for the signal holding unit 15.

When positive voltage is applied to the transfer transistor wiring 6 of the transfer unit 5 and the electrode 18 of the MOS-type capacitance, the charge Q1 of the light receiving unit 2 is transferred to an N-type semiconductor region of the signal holding unit 15. After the above, zero or negative voltage is applied to the transfer transistor wiring 6 of the transfer unit 5 and the electrode 18 of the MOS type capacitance, and the charge Q1 of the light receiving unit 2 is held in the N-type semiconductor region under the electrode 18 of the MOS type capacitance.

In particular, it is possible to suppress leakage charge generated on a surface of the N-type semiconductor of the signal holding unit 15 in a state where negative voltage is applied to the electrode 18 of the MOS type capacitance, so that it is possible to prevent leakage charge from being mixed into the charge Q1 accumulated in the signal holding unit 15, and it is possible to realize excellent SN.

Next, when positive voltage is applied to the reading transistor wiring 17 of the reading unit 16, all the charges Q1 held in the N-type semiconductor region are read out to the FD 7.

At this time, voltage of the FD 7 becomes V1=Q÷C1, and becomes the same voltage V1 as that of the CMOS image sensor of the line sequential reading system of FIG. 16. Therefore, as compared with both the structure of the signal holding unit 15 using the N+ type semiconductor of FIG. 20 and the structure of the signal holding unit 15 using the MIM capacitance of FIG. 21,

in the structure of the signal holding unit 15 using the MOS type capacitance in FIG. 22, there is no decrease in conversion voltage, and

efficiency of transfer from the light receiving unit 2 to the FD 7 and conversion into the voltage V1 is advantageous, and a large signal can be extracted.

From the above, as compared with the structure of the signal holding unit 15 using the N+ type semiconductor in FIG. 20 and the structure of the signal holding unit 15 using the MIM capacitance in FIG. 21, the structure of the signal holding unit 15 using the MOS type capacitance in FIG. 22 has an advantage that efficiency of transfer from the light receiving unit 2 to the FD 7 and conversion into the voltage V1 is excellent, and an amount of leakage charge is small, so that SN is high.

FIG. 23-1 illustrates a pixel in which a light receiving unit, a signal holding unit, and an output unit are linearly arranged on four sides of the light receiving unit. The light receiving unit 2 has a quadrangular shape having four sides parallel to sides of the square pixel 1. The signal holding unit 15 (15-1, 15-2, 15-3, and 15-4) and the output unit 3 (3-1, 3-2, 3-3, 4-4) are linearly arranged in the order of the light receiving unit, the signal holding unit, and the output unit in a vertical direction with respect to each of four sides of the quadrangular light receiving unit 2.

For this reason, for example, in a case where charge of the light receiving unit 2 is linearly transferred to the signal holding unit 15-1 and the output unit 3-1, since the charge can be linearly transferred, transfer of the charge transferred from the light receiving unit 2 to the signal holding unit 15-1 and transfer of the charge from the signal holding unit 15-1 to the output unit 3-1 are easy, and transfer efficiency of both the transfers can be improved. For this reason, an afterimage can be eliminated on an image.

However, in this configuration, there is a disadvantage that an ineffective region 19 where nothing is arranged is widened at four corners of the pixel 1, and there is a problem that it is difficult to reduce size, increase SN, increase sensitivity, and increase resolution of the pixel 1.

FIG. 23-2 illustrates a pixel in which a light receiving unit and a signal holding unit are arranged in a vertical direction with respect to each of four sides of the quadrangular light receiving unit 2, and an output unit is arranged at a position rotated by 90 degrees.

In FIG. 23-2, charge of the light receiving unit 2 is linearly transferred to the signal holding unit 15-1, then bent in a 90 degree direction perpendicular to the linear transfer, and transferred from the signal holding unit 15-1 to the output unit 3-1. In the case of this structure, there is an advantage that the ineffective region 19 at four corners can be slightly narrowed, and a configuration described in Patent Document 1 is obtained.

However, after being transferred from the light receiving unit 2 to the signal holding unit 15-1, charge of the light receiving unit 2 needs to be bent in a right angle direction and transferred from the signal holding unit 15-1 to the output unit 3-1. For this reason, there is a disadvantage that transfer efficiency of charge is deteriorated, and a charge residue is generated in the signal holding unit 15-1, and an afterimage is generated on an image. In particular, in the case of the signal holding unit using the MOS type capacitance illustrated in FIG. 22, it is necessary to transfer all charges of the light receiving unit 2, and thus, when transfer efficiency deteriorates, a problem of a particularly large afterimage occurs.

As described above, the pixel structure of FIG. 23-1 has a large problem of the ineffective region 19, and problems of downsizing, high SN, high sensitivity, and high resolution of the pixel 1. The pixel structure of FIG. 23-2 has a problem of charge transfer efficiency and a problem of an afterimage. Therefore, in the pixel structures of FIGS. 23-1 and 23-2, there is a disadvantage that both the problem of the ineffective region 19 and the problem of the transfer efficiency cannot be solved at the same time.

For comparison, the case of the FD holding type global shutter system using a conventional CMOS image sensor illustrated in FIG. 14 will be compared with FIGS. 23-1 and 23-2. In the case of FIG. 14, since the pixel 1 has a simple structure including only two types of the light receiving unit 2 and the output unit 3, the output unit 3 can be easily arranged anywhere in upper, lower, left, right, and oblique directions of the light receiving unit 2. Therefore, the ineffective region 19 is small, and a large problem of transfer efficiency does not occur, which is advantageous. However, as compared with FIGS. 23-1 and 23-2, there is a large problem of SN due to leakage charge noise generated in the N+ type semiconductor of the FD 7.

As described above, the problem of the CMOS image sensor of the global shutter system is described above.

Means for solving the problems of sensitivity and resolution are proposed in Patent Documents 2 and 3.

These documents relate to a CMOS image sensor in which pixels are arranged in a honeycomb arrangement or a clear bit arrangement where the pixels are rotated by 45 degrees when a plurality of quadrangular pixels are arranged vertically and horizontally.

This structure is a method of simply rotating a pixel by 45 degrees, and is a method that has been well known conventionally in a pixel of a CCD, and some sort of contrivance is required for further increasing sensitivity and resolution.

### PRIOR ART DOCUMENT

### Patent Documents

Patent Document 1: Japanese Patent Laid-open Publication No. 2020-13909
Patent Document 2: Japanese Patent Laid-open Publication No. 2009-296276
Patent Document 3: Japanese Patent Laid-open Publication No. 2014-22415

### SUMMARY OF THE INVENTION

### Problems to be Solved by the Invention

However, as described above, in the case of the CMOS image sensor having the signal holding unit and the output unit adjacent to the light receiving unit of the pixel, there are a problem that efficiency of transmitting signal charge of the light receiving unit to be transmitted to the output unit via the signal holding unit is poor, and a problem that there are many ineffective regions in which the light receiving unit, the signal holding unit, and the output unit are not arranged in the pixel. In the past, since it has been difficult to solve both of these two problems, it has been difficult to reduce size, increase SN, increase sensitivity, increase resolution, and reduce an afterimage of the pixel.

In particular, in the case of a CMOS image sensor having the signal holding unit using the MOS type capacitance, since drive voltage is 3.3 V and is lower than transfer voltage 12 V of a CCD, it has been difficult to eliminate an afterimage by setting transfer efficiency of charge of the light receiving unit to be transferred from the light receiving unit to the signal holding unit and transfer efficiency of charge from the signal holding unit to the output unit to 100%.

Furthermore, in the CMOS image sensor having a plurality of sets of signal holding units and output units in one pixel, downsizing, high SN, high sensitivity, high resolution, and a reduced afterimage have been more major problems.

An object of the present invention is to provide an imaging device or an electronic device including the imaging device, which can achieve, in a pixel having a signal holding unit and an output unit adjacent to a light receiving unit, a reduced afterimage with excellent transfer efficiency for transferring charge of the light receiving unit to the output unit via the signal holding unit, and reduction in size, high SN, high sensitivity, and high resolution of the pixel.

### Solutions to the Problems

In an imaging device having a plurality of pixels having a plurality of vertexes periodically arranged on a plane, each of the plurality of pixels is configured to include a light receiving unit that photoelectrically converts incident light to generate signal charge, a signal holding unit that holds the signal charge transferred from the light receiving unit, and an output unit that detects the signal charge read out from the signal holding unit, the output unit is located at one of the vertexes of the pixel, and the signal holding unit is located between the light receiving unit and the output unit.

In a case where the pixel includes any one of a transfer unit between the light receiving unit and the signal holding unit and a reading unit between the signal holding unit and the output unit, any one of the transfer unit and the reading unit and the signal holding unit are linearly arranged between the light receiving unit and the output unit.

In a case where the pixel includes both of a transfer unit between the light receiving unit and the signal holding unit and a reading unit between the signal holding unit and the output unit, the transfer unit, the signal holding unit, and the reading unit are linearly arranged between the light receiving unit and the output unit.

in a case where the pixel includes the transfer unit, an electrode included in the signal holding unit and an electrode included in the transfer unit are integrated, or common voltage is applied to an electrode included in the signal holding unit and an electrode of the transfer unit.

In the pixel, the signal holding unit is configured to use an N type semiconductor layer for signal holding in a MOS type structure including an electrode, an oxide film, and a semiconductor, and voltage of the electrode unit is zero or negative voltage during a period in which the signal charge is held in the signal holding unit.

In the pixel, a shape of a boundary region between the signal holding unit and the light receiving unit has an inclination of less than 90 degrees with respect to a shape of a boundary region with the pixel adjacent to the pixel.

The pixels are arranged in a matrix with along two axes intersecting at 90 degrees on an arranged plane.

The inclination is ±45 degrees.

A shape of the pixel having a plurality of vertexes is rectangular, square, rhombic, or trapezoidal.

A shape of a boundary region between the signal holding unit and the light receiving unit is a partial side of a polygon having an even number of sides, a partial side of a polygon obtained by rotating a polygon having an even number of sides by an angle of [180 degrees/(the even number)], or a part of an arc.

A shape of a boundary region between the signal holding unit and the light receiving unit is a shape in which an uneven portion is provided on a side of a part of the polygon, or a shape in which an uneven portion is provided in the arc.

The signal holding unit is a polygon having more sides than a quadrangle.

A plurality of the pixels is arranged in a staggered manner.

In a plurality of the pixels arranged in a staggered manner, a pixel in an n-th row of a staggered array and a pixel in an n+1-th row of the staggered array are adjacent to each other in an oblique direction with respect to a row direction.

In the pixel, the signal holding units are provided in at least two or more locations.

In the pixel, the output unit is shared by two or more adjacent ones of the pixels.

### Effects of the Invention

As an imaging device of the present invention, there is provided an imaging device that has excellent transfer efficiency of transferring charge of a light receiving unit to an output unit via a signal holding unit, and can realize reduction in size of a pixel, high SN, high sensitivity, high resolution, and a reduced afterimage.

### BRIEF DESCRIPTION OF THE DRAWINGS

FIG. 1 is a diagram illustrating a first square/rhombus pixel configuration of the present invention.

FIG. 2 is a diagram illustrating a pixel configuration including three sets of signal holding units and output units.

FIG. 3 is a diagram illustrating a pixel configuration including four sets of the signal holding unit and the output unit, and a diagram illustrating a pixel configuration including four sets of the signal holding units having a large area and the output units.

FIG. 4 is a diagram illustrating a pixel configuration including four sets of the signal holding units, the output units, transfer units, and reading units.

FIG. 5 is a diagram illustrating a pixel configuration including four sets of the signal holding units, the output units, and the reading units.

FIG. 6 is a diagram illustrating a cross-sectional structure of a semiconductor of a pixel of a CMOS image sensor of the present invention.

FIG. 7 is a diagram illustrating a pixel configuration having hexagonal and octagonal light receiving units.

FIG. 8 is a diagram illustrating a pixel configuration in which an uneven portion is provided on a side of the light receiving unit obtained by rotating a quadrangle by 45 degrees.

FIG. 9 is a diagram illustrating a pixel configuration in which the octagonal light receiving unit is rotated by 180 degrees÷(eight as the number of sides of octagon)=22.5 degrees and incorporated into a pixel, and a diagram illustrating a pixel configuration having a circular light receiving unit.

FIG. 10 is a diagram illustrating a second pixel configuration of the present invention in which a first pixel of the present invention is rotated by 45 degrees.

FIG. 11 is an arrangement diagram in which a plurality of the second pixels of the present invention are arranged in a staggered manner.

FIG. 12 is an arrangement diagram in which a plurality of the second pixels of the present invention are arranged in a staggered manner, and the output unit is shared by four adjacent pixels.

FIG. 13 is a diagram of a pixel of a conventional general CMOS image sensor.

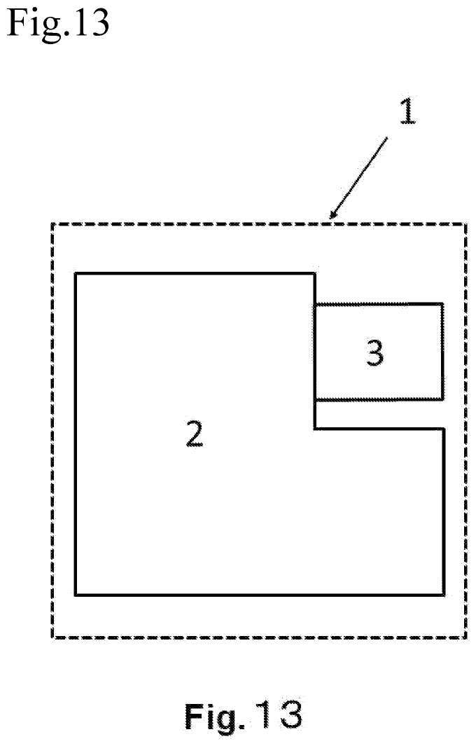

FIG. 14 is an arrangement diagram of a conventional CMOS image sensor in which quadrangular pixels are arranged vertically and horizontally.

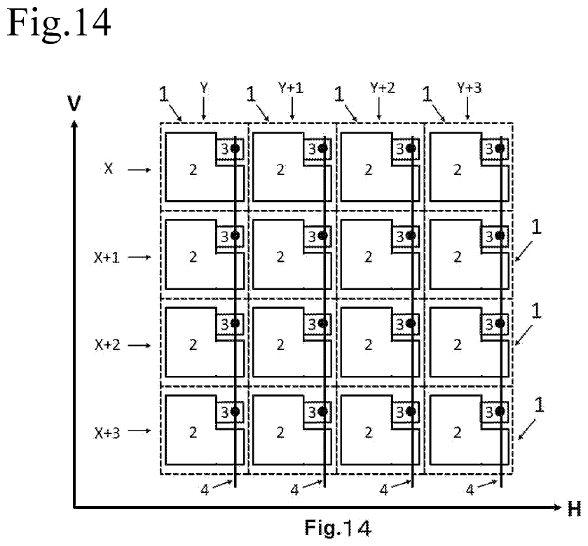

FIG. 15 is a circuit diagram of a pixel of a line sequential reading system.

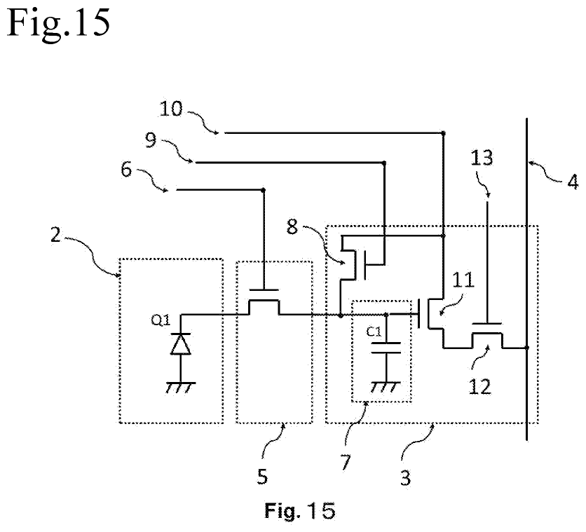

FIG. 16 is a cross-sectional structure of a semiconductor of a pixel of a CMOS image sensor.

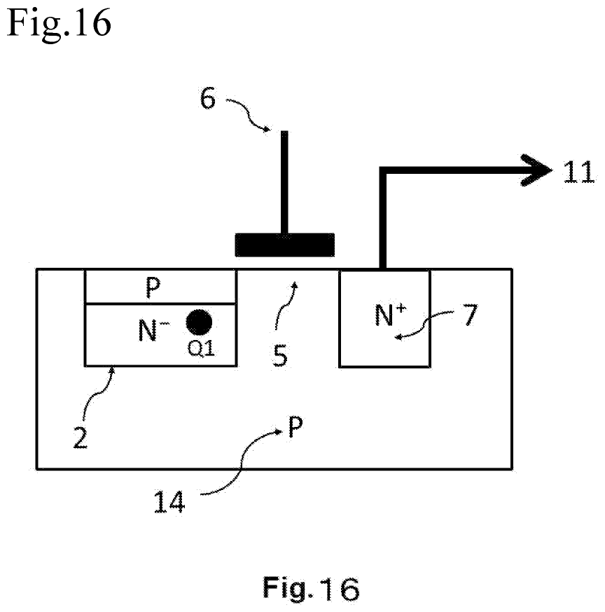

FIG. 17 is a diagram of a pixel of a CMOS image sensor of a conventional charge holding type global shutter system.

FIG. 18 is an arrangement diagram of a CMOS image sensor in which pixels of a charge holding type global shutter system are arranged vertically and horizontally.

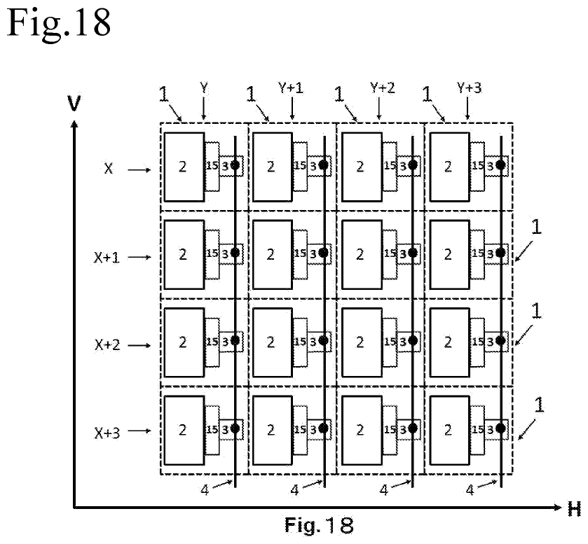

FIG. 19 is a circuit diagram of a pixel of a CMOS image sensor of a charge holding type global shutter system.

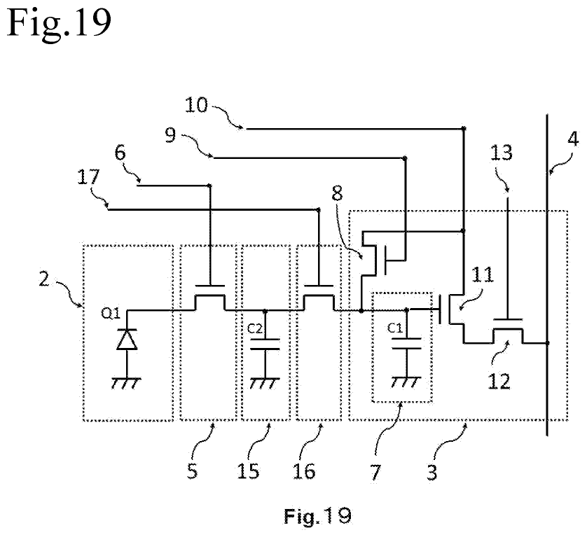

FIG. 20 is a cross-sectional structure diagram of a pixel having a structure of the signal holding unit using an N+ type semiconductor of a Si semiconductor.

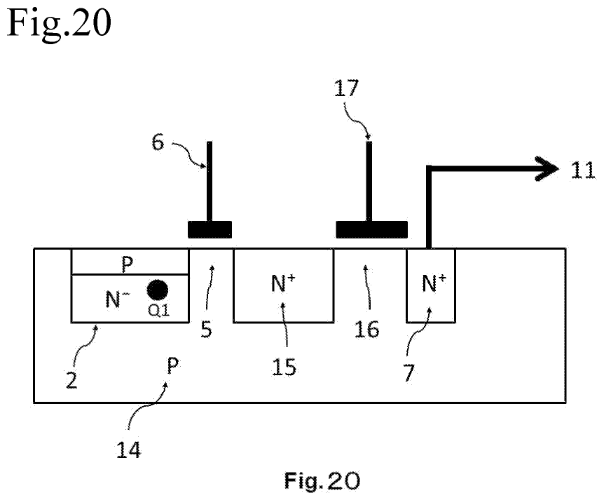

FIG. 21 is a cross-sectional structure diagram of a pixel having a structure of the signal holding unit using metal-insulator-metal (MIM) capacitance.

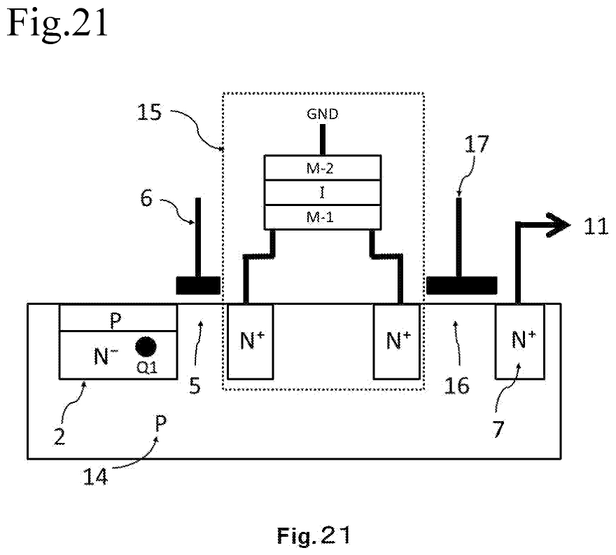

FIG. 22 is a cross-sectional structure diagram of a pixel having a structure of the signal holding unit using MOS type capacitance.

FIG. 23 illustrates a pixel in which the signal holding unit and the output unit are arranged in a straight line in a vertical direction with respect to four sides of the light receiving unit in the light receiving unit of a quadrangular pixel in which a plurality of quadrangular pixels can be arranged horizontally and vertically, and a pixel in which the signal holding unit is arranged in the vertical direction with respect to four sides of the light receiving unit in the light receiving unit of a quadrangular pixel in which a plurality of pixels can be arranged horizontally and vertically, and the output unit is arranged at a position rotated by 90 degrees.

### EMBODIMENT OF THE INVENTION

Provided is an imaging device in which, in a pixel including a light receiving unit, a signal holding unit, and an output unit, transfer efficiency for transfer to the output unit is excellent, and can achieve reduction in size, high SN, high sensitivity, high resolution, and a reduced afterimage of the pixel. Hereinafter, an embodiment of the present invention will be described with reference to the accompanying drawings.

### EXAMPLE

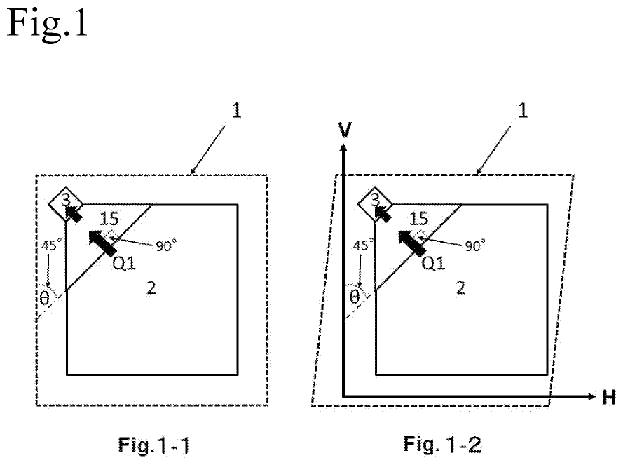

FIG. 1-1 is a diagram illustrating a first square pixel configuration of the present invention.

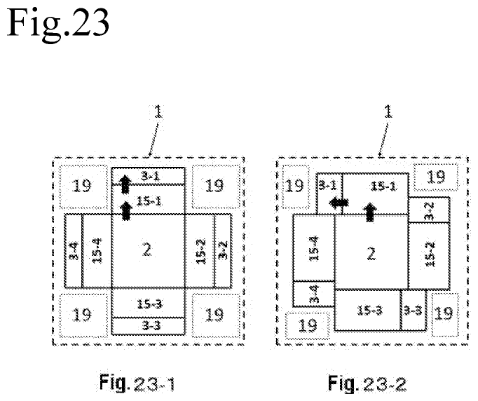

In the first pixel of the present invention, an output unit 3 is arranged at one corner among four corners of a square pixel 1, and a light receiving unit 2, a signal holding unit 15, and an output unit 3 are linearly arranged. With this configuration, an ineffective region 19 as illustrated in FIG. 23 can be minimized in the pixel 1. At this time, a side of the light receiving unit 2 in contact with the signal holding unit 15 is formed with an inclination θ of less than 90 degrees with respect to a vertical side of the pixel 1. By the above, charge Q1 of the light receiving unit 2 that becomes a signal can be linearly transferred from the light receiving unit 2 to the output unit 3 via the signal holding unit 15.

In particular, in a case of a CMOS image sensor including the signal holding unit 15 using MOS type capacitance, both transfer efficiency of charge of transferring the charge Q1 of the light receiving unit 2 from the light receiving unit 2 to the signal holding unit 15 and transfer efficiency of the charge Q1 of the light receiving unit 2 held in the signal holding unit 15 from the signal holding unit 15 to the output unit 3 can be set to 100%.

Further, by forming the output unit 3 at a corner of the pixel and setting an inclination θ of a side of a boundary region of the light receiving unit 2 in contact with the signal holding unit 15 with respect to a vertical side of the pixel 1 to 45 degrees, a direction in which the charge Q1 at the center of the light receiving unit 2 linearly advances to the output unit 3 via the signal holding unit 15 and a side of a boundary region between the signal holding unit 15 and the light receiving unit 2 form a right angle of 90 degrees, so that transfer efficiency of the charge Q1 can be maximized.

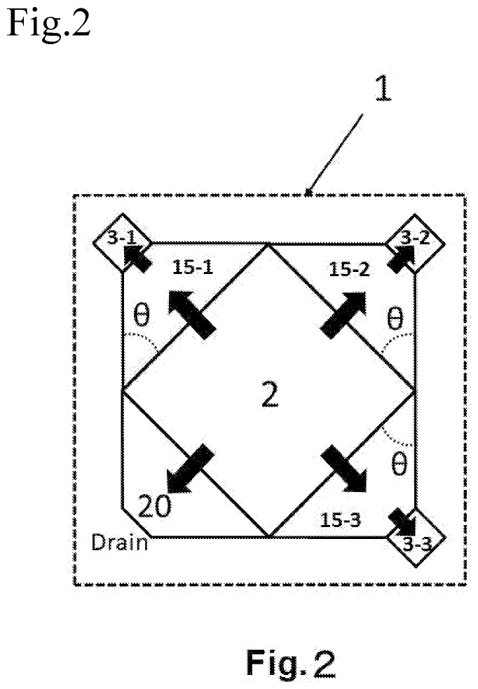

FIG. 1-2 is a diagram illustrating a first rhombus pixel configuration of the present invention.

In FIGS. 1-1 and 1-2, the shape of the pixel 1 is different, but the light receiving unit 2, the signal holding unit 15, and the output unit 3 are exactly the same, and only a periphery of the pixel is different between square and rhombus.

In FIG. 1-2, a direction parallel to a vertical side of the square pixel 1 of FIG. 1-1 is defined as a vertical axis (V) direction, and a direction parallel to a horizontal side of the square pixel 1 of FIG. 1-1 is defined as a horizontal axis (H) direction.

In the square pixel 1 in FIG. 1-1, a vertical side of the pixel 1 and a side of the light receiving unit 2 are parallel. In the rhombic pixel 1 in FIG. 1-2, the vertical axis (V) and a side of the light receiving unit 2 are parallel. The light receiving unit 2, the signal holding unit 15, and the output unit 3 have exactly the same configuration.

Therefore, in FIG. 1-2, by making a side of a boundary region of the light receiving unit 2 in contact with the signal holding unit 15 have an inclination of 45 degrees with respect to the vertical axis (V), a direction in which the charge Q1 at the center of the light receiving unit 2 linearly advances to the output unit 3 via the signal holding unit 15 and a side of a boundary region between the signal holding unit 15 and the light receiving unit 2 form a right angle of 90 degrees, and thus, similarly to FIG. 1-1, transfer efficiency of the charge Q1 can be maximized.

Further, in FIG. 1-1, by setting the inclination θ formed between a side of the boundary region between the signal holding unit 15 and the light receiving unit 2 of the pixel 1 and the vertical side of the pixel 1 to 45 degrees, transfer efficiency of the charge Q1 of the light receiving unit 2 can be maximized. Similarly, in FIG. 1-2, by setting the inclination θ formed between the side of the boundary region between the signal holding unit 15 and the light receiving unit 2 of the rhombic pixel 1 and the vertical axis (V) to 45 degrees, transfer efficiency of the charge Q1 of the light receiving unit 2 can be maximized.

Therefore, regardless of whether the shape of the pixel 1 is a square or a rhombus, as long as the light receiving unit 2, the signal holding unit 15, and the output unit 3 have exactly the same configuration, the configuration for improving the transfer efficiency is the same regardless of the shape of the pixel 1.

The light receiving unit 2, the signal holding unit 15, and the output unit 3 can be arranged exactly in the same manner in the entire pixel region between the pixel region in a case where the square pixels of FIG. 1-1 are periodically arranged in a matrix form horizontally and vertically at the pitch of the vertical dimension and the pitch of the horizontal dimension of the pixels 1 and the pixel region in a case where the rhombic pixels 1 of FIG. 1-2 are periodically arranged in a matrix form horizontally and vertically at the pitch of the vertical dimension and the pitch of the horizontal dimension similar to FIG. 1-1.

For this reason, even if the shape around the pixels 1 is a trapezoid or a curve other than a square or a rhombus, if the light receiving unit 2, the signal holding unit 15, and the output unit 3 have exactly the same configuration, the pixel region in a case of periodical arrangement in a matrix form in horizontal and vertical directions at the pitch of the vertical dimension and the pitch of the horizontal dimension similar to that in FIG. 1-1 can have substantially the same shape.

Therefore, by setting the inclination θ formed by the side of the boundary region between the signal holding unit 15 and the light receiving unit 2 of the pixel 1 and the vertical axis (V) to less than 90 degrees, transfer efficiency of the charge Q1 of the light receiving unit 2 can be improved similarly to FIG. 1-1 regardless of a peripheral shape of the pixel. In a case where θ is 45 degrees, an effect of improving the transfer efficiency can be further increased.

As described above, by linearly arranging the light receiving unit 2, the signal holding unit 15, and the output unit 3 arranged at a corner of the quadrangular pixel 1, it is possible to improve the transfer efficiency of transferring the charge Q1 of the light receiving unit 2 to be a signal to the output unit 3 with a smallest area of the ineffective region 19.

As a result, since an amount of charge remaining in the signal holding unit 15 can be reduced in a case where the transfer efficiency is poor, an afterimage phenomenon of an image caused by the charge remaining in the signal holding unit 15 can be reduced as much as possible. In particular, in a CMOS image sensor including the signal holding unit 15 using MOS type capacitance, since 100% transfer efficiency can be realized, an afterimage on an image is eliminated, and the effect is great.

Further, since the charge Q1 of the light receiving unit 2, which becomes a signal, can be most efficiently transferred to the output unit 3, output voltage converted from the charge Q1 of the pixel 1 can be increased.

From the above, as an effect of minimizing the ineffective region 19 of the pixel 1, it is possible to reduce size, increase SN, and increase sensitivity of the pixel. Further, if reduction in size of the pixel can be realized, the number of pixels of the imaging device can be increased, so that high resolution can be realized. Further, as an effect of improving charge transfer efficiency, a reduced afterimage can be realized.

FIGS. 2, 3-1, and 3-2 are diagrams illustrating a configuration of the pixel 1 including a plurality of sets of the signal holding units 15 and the output units 3.

FIG. 2 is a diagram illustrating a pixel configuration including three sets of the signal holding units and the output units.

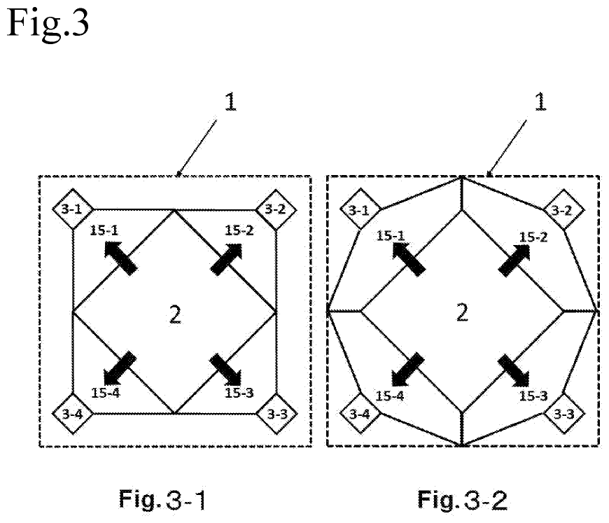

FIG. 3-1 is a diagram illustrating a pixel configuration including four sets of the signal holding units and the output units.

FIG. 3-2 is a diagram illustrating a pixel configuration including four sets of the signal holding units having a large area and the output units.

In FIG. 2, among four corners of the quadrangular pixel 1, the signal holding unit 15 and the output unit 3 are arranged toward three corners, and drain 20 for discharging unnecessary charge is arranged at one corner.

A side of a boundary between the signal holding unit 15 and the output unit 3 arranged toward three corners is formed with the inclination θ with respect to a vertical side of the pixel 1, similarly to FIG. 1.

On the other hand, a side of a boundary between the drain 20 without the signal holding unit 15 or the output unit 3 and the light receiving unit 2 does not need to have the same inclination θ with respect to the vertical side of the square pixel 1.

For example, in a case where θ=45° described above, in FIG. 2, an angle between a side of a boundary between the drain 20 and the light receiving unit 2 and the vertical side of the square pixel 1 is 45°, which is the same as θ described above. However, in practice, the angle in the drain may be 90° or 0°, which is an angle different from θ, and there is no problem as long as a structure capable of discharging unnecessary charge is employed.

In FIGS. 3-1 and 3-2, the signal holding unit 15 and the output unit 3 are arranged from the light receiving unit 2 in the quadrangular pixel 1 toward four corners of the pixel 1.

FIG. 3-1 illustrates a configuration in which an area of the signal holding unit 15 is reduced and size of the light receiving unit 2 is prioritized, a structure focusing on high sensitivity is employed, and the signal holding unit 15 has a quadrangular structure close to a trapezoid.

FIG. 3-2 illustrates a configuration in which an area of the signal holding unit 15 is increased, a structure in which an amount of charge that can be held in the signal holding unit 15 is increased and emphasis is placed on a dynamic range is employed, and the signal holding unit 15 has a structure having sides of a hexagon, which are larger in number than a quadrangle.

As illustrated in FIGS. 23-1 and 23-2, in the CMOS image sensor of a conventional global shutter system having a plurality of sets of the signal holding units 15 and the output units 3 around the light receiving unit 2 of the pixel 1, there is a problem that the ineffective region 19 is large. However, in FIGS. 2, 3-1, and 3-2, since the ineffective region 19 is extremely small, reduction in size of the pixel 1 and high sensitivity of the light receiving unit 2 can be realized.

Further, the light receiving unit 2 of the pixel 1 in FIGS. 2, 3-1, and 3-2 has a shape obtained by rotating a quadrangle having horizontal and vertical sides by 45 degrees, and an area of the light receiving unit 2 is larger than that of the conventional light receiving unit 2 having a shape obtained by not rotating a quadrangle having horizontal and vertical sides by 45 degrees illustrated in FIGS. 23-1, and 23-2.

Therefore, the pixel 1 in FIGS. 2, 3-1, and 3-2 can achieve higher sensitivity than the conventional pixel 1 illustrated in FIGS. 23-1, and 23-2.

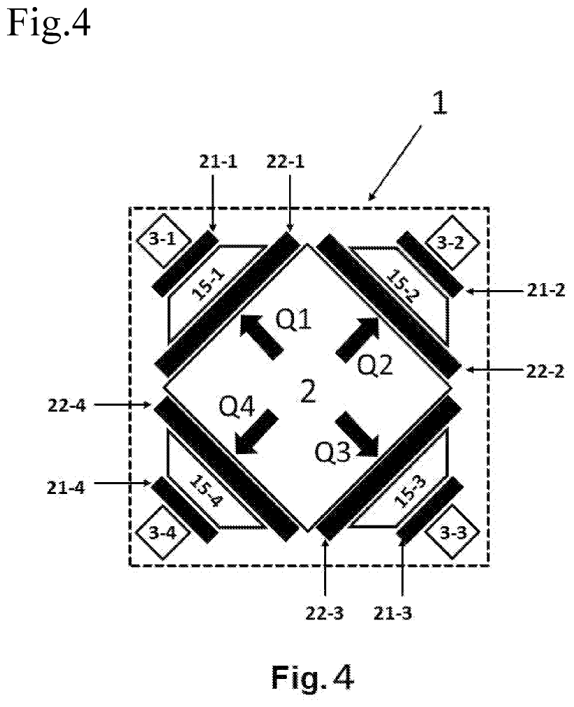

FIG. 4 is a diagram illustrating a pixel configuration including four sets of the signal holding units, the output units, the transfer units, and the reading units. When an electrode of a transfer electrode 22-1 is turned on, the charge Q1 of the light receiving unit 2 is transferred to the signal holding unit 15-1 and then held. During a next different time period, when an electrode of a transfer electrode 22-2 is turned on, charge Q2 of the light receiving unit 2 is transferred to the signal holding unit 15-2 and then held. Similarly, when an electrode of a transfer electrode 22-3 is turned on at a different time period, charge Q3 of the light receiving unit 2 is transferred to the signal holding unit 15-3 and then held. Similarly, when an electrode of a transfer electrode 22-4 is turned on at a different time period, charge Q4 of the light receiving unit 2 is transferred to the signal holding unit 15-4 and then held.

Through the above operation, charges are transferred at high speed inside the pixel to all of the signal holding unit 15-1, the signal holding unit 15-2, the signal holding unit 15-3, and the signal holding unit 15-4, and held.

After the above, when a reading unit 21-1 is turned on, the charge Q1 held in the signal holding unit 15-1 is read out to the output unit 3-1. Next, when a reading unit 21-2 is turned on, the charge Q2 held in the signal holding unit 15-2 is read out to the output unit 3-2. Next, when a reading unit 21-3 is turned on, the charge Q3 held in the signal holding unit 15-3 is read out to the output unit 3-3. Next, when a reading unit 21-4 is turned on, the charge Q4 held in the signal holding unit 15-4 is read out to the output unit 3-4.

In each pixel of the present invention, charge of the light receiving unit is transferred to four locations of the signal holding unit 15-1, the signal holding unit 15-2, the signal holding unit 15-3, and the signal holding unit 15-4 by the same operation as in FIG. 4, and thus, it is possible to read out signals for four frames to four of the signal holding units 15 of all the pixels at high speed.

Therefore, a CMOS image sensor of a global shutter system for four frames can be realized.

Further, by using this structure, a CMOS image sensor for time of flight (ToF) for measuring a distance can also be realized.

In FIG. 4, the transfer electrode 22-1, the signal holding unit 15-1, the reading electrode 21-1, and the output unit 3-1 can all be arranged linearly in a direction in which the charge Q1 of the light receiving unit 2 moves.

For this reason, deterioration of transfer efficiency of transferring the charge Q1 from the light receiving unit 2 to the output unit 3-1 can be eliminated, and FIG. 4 of the present invention illustrates a pixel structure advantageous for charge transfer.

In particular, in a case of a CMOS image sensor including the signal holding unit 15 using MOS type capacitance, in order to eliminate an afterimage phenomenon occurring on an image, it is necessary to eliminate charge remaining in the signal holding unit 15 due to poor transfer efficiency. For this reason, for the charge Q1 of the light receiving unit 2, it is required to set both transfer efficiency of charge transferred from the light receiving unit 2 to the signal holding unit 15 and transfer efficiency of charge from the signal holding unit 15 to the output unit 3 to 100%.

Therefore, in the CMOS image sensor including the signal holding unit 15 using the MOS type capacitance,

the light receiving unit 2, the transfer electrode 22-1, the signal holding unit 15-1, the reading unit 21-1, and

the output unit 3-1 are all arranged linearly, which is most effective in improving the transfer efficiency, and it is possible to realize an image with a reduced afterimage.

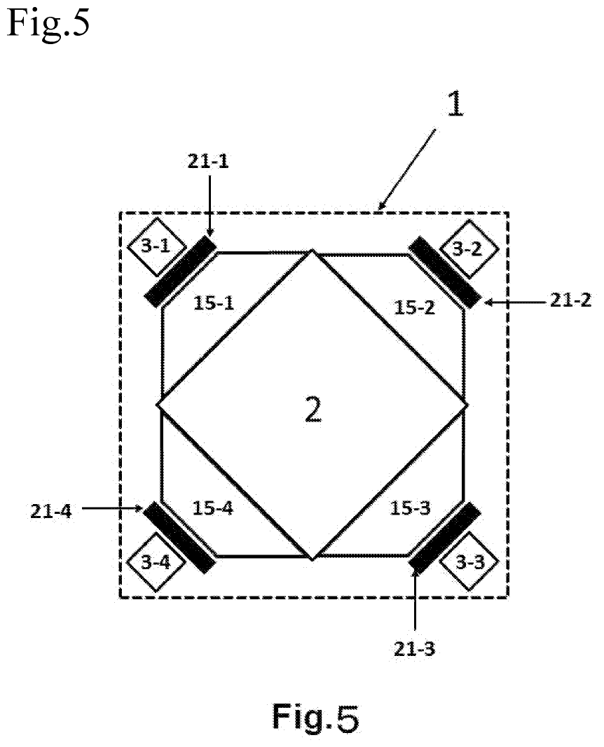

FIG. 5 is a diagram illustrating a pixel configuration including four sets of the signal holding units, the output units, and the reading units.

FIG. 5 illustrates a configuration in which the transfer electrode 22 is omitted from the configuration of FIG. 4. In order to realize reduction in size of the pixel 1 by enlarging an area of the signal holding unit 15 and enlarging an area of the light receiving unit 2, it is an effective means to reduce the number of electrodes.

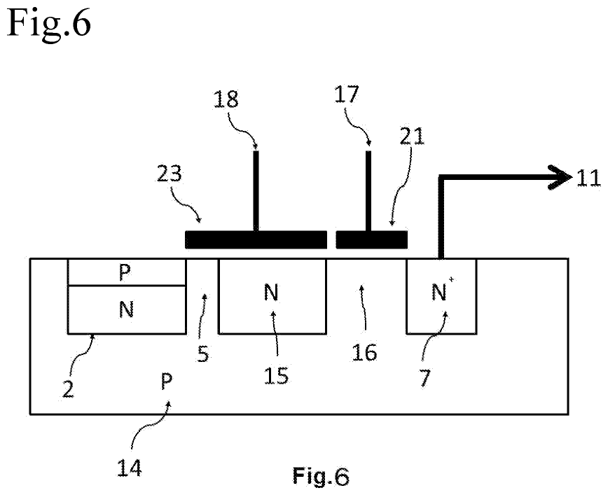

FIG. 6 is a diagram illustrating a cross-sectional structure of a semiconductor of a pixel of a CMOS image sensor of the present invention.

FIG. 6 illustrates the CMOS image sensor including the signal holding unit 15 using MOS type capacitance, and

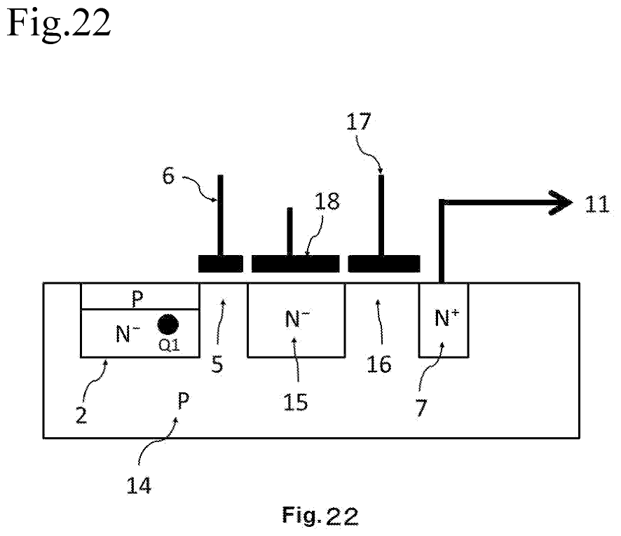

on the transfer unit 5 and the signal holding unit 15, an electrode 23 serving as both a transfer electrode and an electrode of the MOS type capacitance is formed, and the number of electrodes and the number of wirings to the electrodes can be reduced by one as compared with FIG. 22. During a period in which a signal is held in the signal holding unit, zero or negative voltage is applied to an electrode, so that leakage charge can be suppressed.

In FIG. 5, since the number of electrodes and the number of wires to the electrodes can be reduced by one in all the signal holding units (15-1, 15-2, 15-3, and 15-4), reduction in size, high SN, high sensitivity, and high pixel can be realized in the pixel 1 of the present invention.

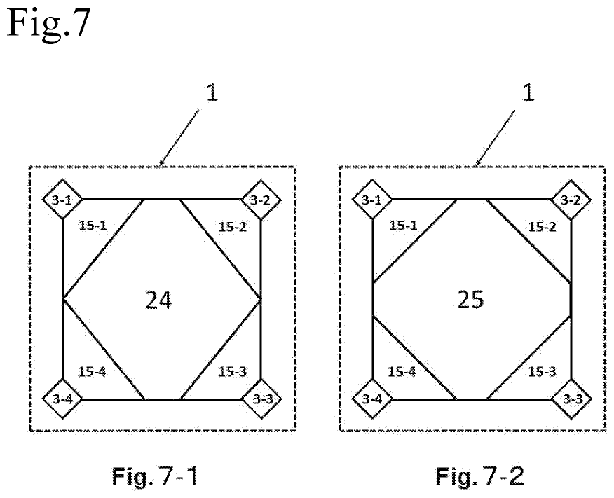

FIG. 7-1 is a diagram illustrating a pixel configuration having a hexagonal light receiving unit.

FIG. 7-2 is a diagram illustrating a pixel configuration including an octagonal light receiving unit.

The light receiving unit 2 in FIG. 3-1 has a shape obtained by rotating a quadrangle having a horizontal base by 45 degrees. In a case where the light receiving unit 2 is a quadrangle, there is a disadvantage that an area of the light receiving unit 2 becomes small. In order to balance areas of the light receiving unit 2 and the signal holding unit 15 while enlarging the light receiving unit 2, the pixel 1 in FIG. 7-1 is a hexagonal light receiving unit 24.

A boundary region between the hexagonal light receiving unit 24 and the signal holding unit 15 is a long side among sides of a hexagon and is a side inclined with respect to a horizontal axis of the pixel. By the above, in a case where charge of the hexagonal light receiving unit 24 is read out from the signal holding unit 15, a structure with excellent transfer efficiency can be realized.

In the pixel 1 of FIG. 7-2, an octagonal light receiving unit 25 is provided in order to balance the areas of the light receiving unit 2 and the signal holding unit 15 while enlarging the light receiving unit 2. In contrast to the hexagonal light receiving unit 24 in FIG. 7-1, an even polygon having a large number of sides is provided as the octagonal light receiving unit 25, and an effect of increasing size of the light receiving unit 2 to improve sensitivity is large.

A boundary region between the octagonal light receiving unit 25 and the signal holding unit 15 is a long side among sides of an octagon, and is a side having an inclination of 45 degrees with respect to a horizontal axis of the pixel. By the above, in a case where charge of the octagonal light receiving unit 25 is read out from the signal holding unit 15, a structure with excellent transfer efficiency can be realized.

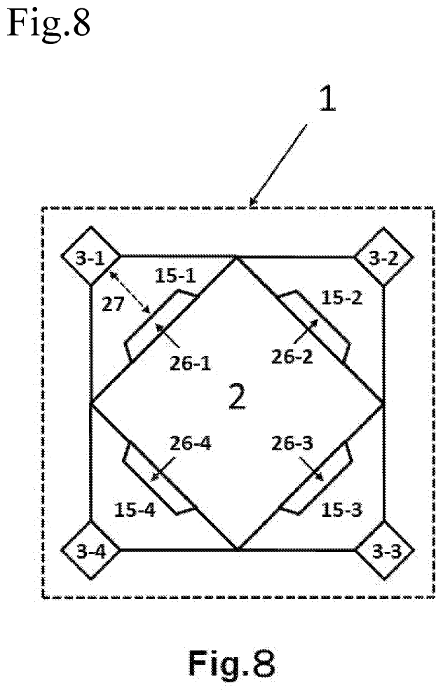

FIG. 8 is a diagram illustrating a pixel configuration in which an uneven portion is provided on a side of a light receiving unit obtained by rotating a quadrangle having horizontal and vertical sides by 45 degrees.

FIG. 8 illustrates a shape in which an uneven portion 26 is provided in a boundary region between the light receiving unit 2 and the signal holding unit 15 in FIG. 3-1. In the case of FIG. 8, by providing the uneven portion 26 in the boundary region, there is an effect of widening the light receiving unit 2 and improving sensitivity.

Further, by shortening a charge transfer distance 27 in the signal holding unit between an uneven portion 26-1 of the light receiving unit 2 and the output unit 3-1, a distance by which charge of the light receiving unit 2 passes through the signal holding unit 15-1 is shortened, so that there is an effect that transfer efficiency of charge in the signal holding unit 15-1 can be improved.

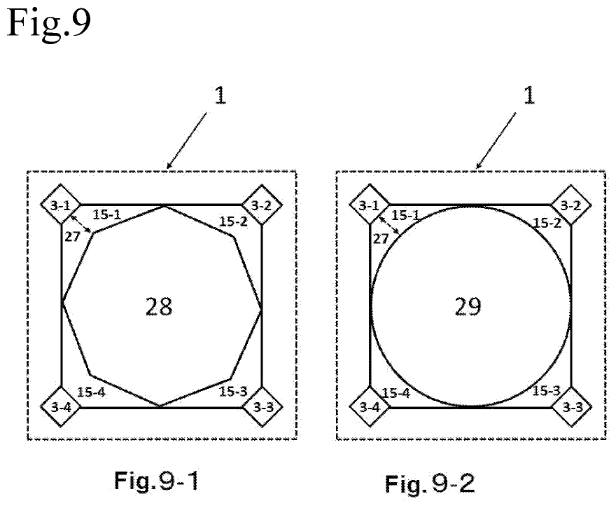

FIG. 9-1 is a diagram illustrating a pixel configuration in which an octagonal light receiving unit is rotated by 180 degrees÷(8 as the number of sides of an octagon)=22.5 degrees and incorporated into a pixel. FIGS. 7-1 and 9-1 are different from each other in the shape of the octagon, but in FIG. 9-1, a light receiving unit 28 is obtained by rotating the octagon by 22.5 degrees. At this time, since one of vertexes of the light receiving unit 28 obtained by rotating the octagon by 22.5 degrees is in contact with the signal holding unit 15-1, the charge transfer distance 27 in the signal holding unit can be shortened, and there is an effect that charge transfer efficiency can be improved.

This diagram illustrates an octagonal light receiving unit, and by employing a light receiving unit obtained by rotating

180 degrees÷(12 as the number of sides of a dodecagon)=15 degrees in a case of a dodecagonal light receiving unit, and

180 degrees÷(16 as the number of sides of a hexadecagon)=11.25 degrees in a case of a hexadecagonal light receiving unit,

the charge transfer distance 27 in the signal holding unit can be shortened, and there is an effect that charge transfer efficiency can be improved similarly to the case of the light receiving unit 28 obtained by rotating an octagon by 22.5 degrees.

FIG. 9-2 is a diagram illustrating a pixel configuration including a circular light receiving unit.

In FIG. 9-2, a circular light receiving unit 29 has a shape in which a part of an arc is in contact with the signal holding unit 15. In a case of the circular light receiving unit 29, since an area of the light receiving unit can be increased and the charge transfer distance 27 in the signal holding unit can be shortened at the same time in a well-balanced manner, an optimal structure of the light receiving unit 2 is obtained.

As a result, it is possible to simultaneously realize improvement in sensitivity of the circular light receiving unit 29 and improvement in transfer efficiency of charge in the signal holding unit 15-1.

In FIG. 9-2, a boundary region between the circular light receiving unit 29 and the signal holding unit 15 is a part of a circular shape, but the same effect can be obtained even if the boundary region is a part of an elliptical shape.

As described above, by employing the structures of FIGS. 4 to 9-2, it is possible to provide an imaging device capable of further improving a reduced afterimage with excellent transfer efficiency of transferring charge of the light receiving unit to the output unit via the signal holding unit, and further improving reduction in size, high SN, high sensitivity, and high resolution of the pixel.

Further, in the pixels of FIGS. 2 to 9-1 and 9-2, since the output unit 3 is present at two or more of four corners of the pixel 1, in a case where the pixels 1 are periodically arranged in a matrix, the output units 3 are adjacent to each other between the adjacent pixels 1, and thus the output unit 3 can be shared.

In this case, as the output unit 3 is shared between adjacent pixels, it is possible to realize reduction in size of the pixel 1, expansion of the light receiving unit 2, and the like, and thus, it is possible to realize further reduction in size, higher SN, higher sensitivity, and higher resolution of the pixel 1.

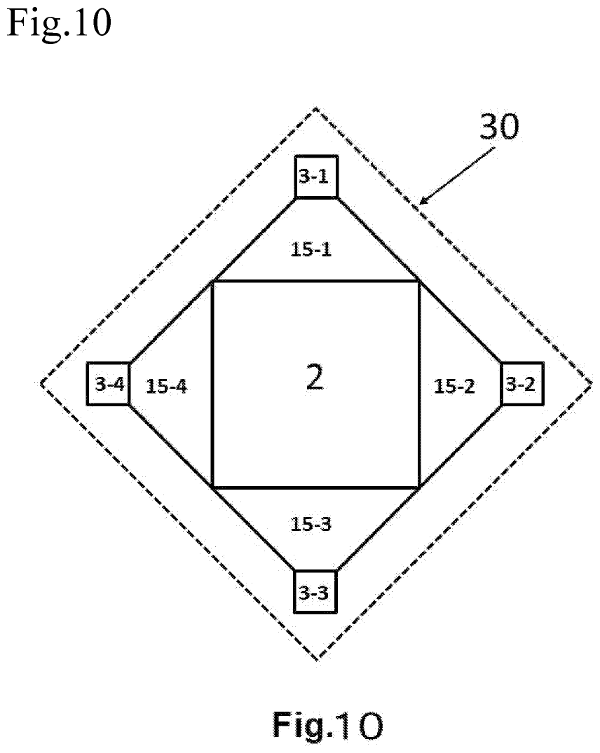

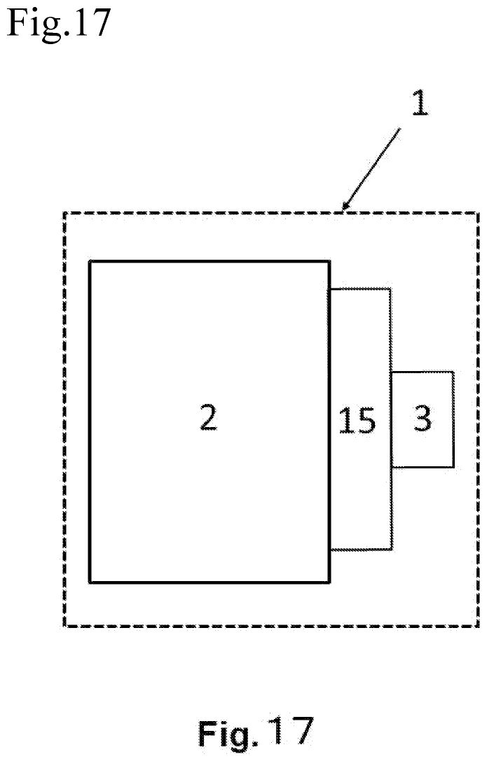

FIG. 10 is a diagram illustrating a configuration of a second pixel of the present invention obtained by rotating the first pixel of the present invention by 45 degrees. The light receiving unit 2 of the pixel of a CMOS image sensor of a conventional charge holding type global shutter system illustrated in FIG. 17 has a quadrangle shape parallel to horizontal and vertical sides of the quadrangular pixel 1. As one of means for increasing sensitivity of a pixel, in addition to improvement of a semiconductor pixel, means for providing a microlens formed of an organic material or the like formed on the pixel is generally used.

In this case, an optimum conventional microlens has been formed in order to realize high sensitivity for the quadrangular light receiving unit 2 having horizontal and vertical sides.

If the pixel 1 in FIG. 17 is simply rotated by 45 degrees, the quadrangular light receiving unit 2 is also rotated by 45 degrees at the same time. Therefore, when a conventional microlens is used on the quadrangular light receiving unit 2 rotated by 45 degrees, a problem of sensitivity reduction occurs.

For this reason, in a case where the conventional pixel 1 is rotated by 45 degrees, it is necessary to develop a dedicated microlens again for the light receiving unit 2 having a quadrangular shape rotated by 45 degrees.

In particular, in a case where the light receiving unit 2 has a rectangular shape different from a square shape, it is particularly necessary to develop a dedicated microlens.

On the other hand, FIG. 10 illustrates a pixel obtained by rotating the first pixel 1 of the present invention described with reference to FIG. 3-1 by 45 degrees. A second pixel structure of the present invention will be referred to as a diamond pixel 30.

In this case, the shape of the light receiving unit 2 in FIG. 10 is a quadrangle having horizontal and vertical sides even though the pixel 1 is rotated by 45 degrees. Therefore, the conventional microlens used in the conventional technique of FIG. 17 can be directly applied to the pixel of FIG. 10, and it is not necessary to develop a new microlens. Therefore, a highly sensitive pixel can be realized without newly developing a microlens.

The reason why the light receiving unit 2 in FIG. 10 is the quadrangular light receiving unit 2 having horizontal and vertical sides is that the light receiving unit 2 already has a shape obtained by rotating the quadrangle by 45 degrees in FIG. 3-1 illustrating the first pixel of the present invention.

The effect that high sensitivity can be obtained using the principle of the conventional microlens is obtained because the first pixel of the present invention can be rotated by 45 degrees, and it can be said that the second pixel arrangement of the present invention is pixel arrangement that further enhances the superiority of high sensitivity of the first pixel configuration of the present invention.

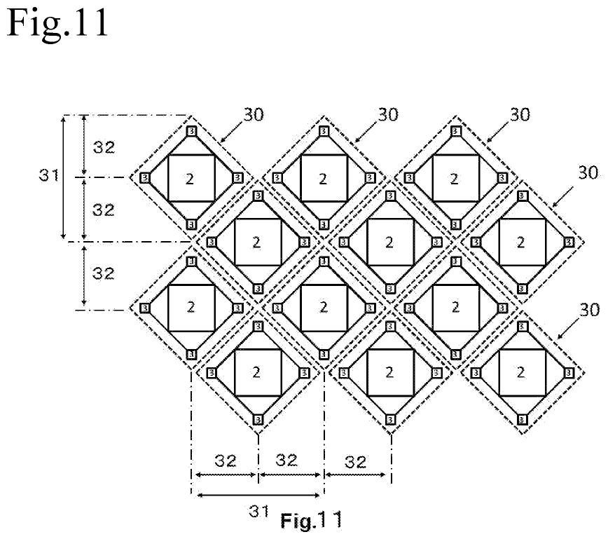

FIG. 11 is an arrangement diagram in which a plurality of the second pixels of the present invention are arranged in a staggered manner.

A structure in which a plurality of pieces are arranged in a staggered manner is conventionally called honeycomb arrangement or clear bit arrangement.

A configuration in which a plurality of the diamond pixels 30, which are the second pixels of the present invention, are arranged in a staggered manner is referred to as a diamond array.

By arranging the diamond pixels 30 in a staggered manner, a resolution pitch 32 is half a pixel pitch 31 with respect to the pixel pitch 31.

For this reason, for horizontal and vertical resolution, a resolution twice the pixel pitch can be realized.

Therefore, the CMOS image sensor in which a plurality of pieces are arranged in a staggered manner illustrated in FIG. 11 can realize high resolution while maintaining high sensitivity as described in FIG. 10.

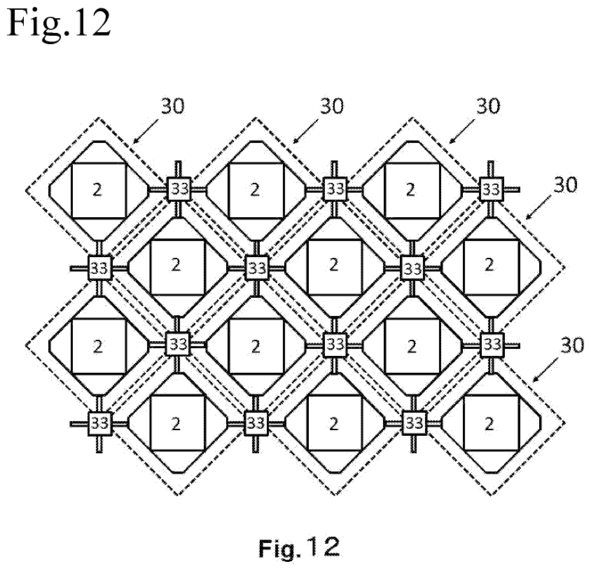

FIG. 12 is an arrangement diagram in which a plurality of the second pixels of the present invention are arranged in a staggered manner, and the output unit is shared by four adjacent pixels. In FIG. 11, the output unit 3 is located at four corners in each of the diamond pixels 30, but in FIG. 12, four adjacent ones of the diamond pixels 30 can share four positions of the output unit 3 closest to each other, and a shared output unit 33 can be configured.

A factor that makes this structure possible is that the output units 3 can be effectively arranged at four corners of the quadrangular pixel 1 as in the configuration of the first pixel of the present invention illustrated in FIG. 3-1.

As a result, with respect to the diamond array in which a plurality of the diamond pixels 30, which are the second pixel of the present invention, are arranged in a staggered manner, adjacent four of the diamond pixels 30 share four of the output units 3 closest to each other, so that it is possible to realize reduction in size, high SN, high sensitivity, high resolution, and a reduced afterimage of the diamond pixel 30.

In either case of FIGS. 11 and 12, in addition to a reduced afterimage, reduction in size, and high SN of a CMOS image sensor, further high sensitivity and high resolution can be realized, so that the effect is great.

FIG. 10 illustrates a shape obtained by rotating FIG. 3-1, but even in a case where FIG. 3-2, FIG. 4, FIG. 5, FIG. 7-1, FIG. 7-2, FIG. 8, FIG. 9-1, and FIG. 9-2 of the present invention are rotated by 45 degrees and arranged in diamond, there are effects similar to those in FIGS. 11 and 12, and it is possible to realize reduction in size, high sensitivity, high resolution, and a reduced afterimage of the CMOS image sensor using the pixel 1.

FIG. 12 illustrates the case where the output unit 3 is located at four corners of the diamond pixel 30. However, in a case where the output unit is located at two or more of four corners, the shared output unit 33 can be provided.

For this reason, in a case where the output units are present at two or more of four corners, it is possible to realize reduction in size, high SN, high sensitivity, high resolution, and a reduced afterimage of the diamond pixel 30.

In the pixels of FIG. 3-1, FIG. 3-2, FIG. 4, FIG. 5, FIG. 7-1, FIG. 7-2, FIG. 8, FIG. 9-1, FIG. 9-2, and FIG. 10 of the present invention, four sets of the output units 3 and the signal holding units 15 are arranged in four corner regions of the quadrangular pixel 1.

Even in the first pixel of the present invention like the pixel 1 of one set of the output unit 3 and the signal holding unit 15 as illustrated in FIG. 1-1 or the pixel 1 of three sets of the output units 3 and the signal holding units 15 as illustrated in FIG. 2, the diamond array is configured after the pixel 1 is rotated by 45 degrees, the effect of reduction in size, high SN, high sensitivity, high resolution, and a reduced afterimage of a CMOS image sensor is large as in FIG. 11.

Further, in the pixels of FIGS. 1-1 and 1-2, in a case where the diamond array is configured, the output units 3 of adjacent pixels are not close to each other, and the shared output unit 33 as in FIG. 12 cannot be made. However, if there are two or more sets of the output units 3 and the signal holding units 15, there is an effect similar to that of FIG. 12.

Therefore, in the case of the pixels of FIGS. 2, 3-1, 3-2, 4, 5, 7-1, 7-2, 8, 9-1, and 9-2, the diamond array is configured, and the shared output unit 33 that shares the output unit 3 with an adjacent pixel is provided, so that the effect of reduction in size, high SN, high sensitivity, high resolution, and a reduced afterimage of the CMOS image sensor is large as in FIG. 12.

FIG. 2 illustrates a case of the structure having three sets of the output units 3 and the signal holding units 15 and the drain 20.

As illustrated in FIGS. 3-1, 3-2, 4, 5, 7-1, 7-2, 8, 9-1, 9-2, 10, 11, and 12, even in a case where one of four sets of the output units 3 and the signal holding units 15 is the drain, the effect of the output unit 3 and the signal holding unit 15 by the structure shown by the first pixel of the present invention illustrated in FIG. 1 is similar, and thus, the effect of reduction in size, higher SN, higher sensitivity, higher resolution, and a reduced afterimage of the CMOS image sensor is similar.

Further, in FIGS. 3-1, 3-2, 4, 5, 7-1, 7-2, 8, 9-1, 9-2, 10, 11, and 12, there are four sets of the output units 3 and the signal holding units 15, but in a case where one of four sets of the output units 3 and the signal holding units 15 is the drain,

in a boundary region between the drain 20 and the light receiving unit 2, a boundary region between the drain 20 and the light receiving unit 24, a boundary region between the drain 20 and the light receiving unit 25, a boundary region between the drain 20 and the light receiving unit 28, or a boundary region between the drain 20 and the light receiving unit 29, a side of the boundary region between the drain 20 and each of the light receiving units (2, 24, 25, 28, and 29) does not need to have the inclination θ with respect to a vertical side of the quadrangular pixel 1 or a shape of a part of an arc.

The embodiment of the present invention is not limited to the embodiment described above, and can be implemented in various forms including the content of the present invention.

### INDUSTRIAL APPLICABILITY

An electronic device equipped with the imaging device according to the present invention is used in many fields such as a mobile phone, an industrial device camera, a medical camera, and an in-vehicle camera.

### DESCRIPTION OF REFERENCE SIGNS

1: Pixel
2: Light receiving unit
3: Output unit
4: Vertical signal line
5: Transfer unit
6: Transfer transistor wiring
7: Floating diffusion unit
8: Reset transistor
9: Reset transistor wiring
10: Pixel power supply
11: Output transistor
12: Row selection transistor
13: Row selection transistor wiring
14: Semiconductor substrate
15: Signal holding unit
16: Reading unit
17: Reading transistor wiring
18: Electrode of MOS type capacitance
19: Ineffective region
20: Drain
21: Reading electrode
22: Transfer electrode
23: MOS-type capacitance electrode also serving as transfer electrode
24: Hexagonal light receiving unit
25: Octagonal light receiving unit
26: Uneven portion
27: Charge transfer distance in signal holding unit
28: Light receiving unit in which an octagon is rotated by 22.5 degrees
29: Circular light receiving unit
30: Diamond pixel
31: Pixel pitch
32: Resolution pitch
33: Shared output unit

1. An imaging device having a plurality of pixels having a plurality of vertexes periodically arranged on a plane, the imaging device being characterized in that:
each of the plurality of pixels is configured to include
a light receiving unit that photoelectrically converts incident light to generate signal charge,
a signal holding unit that holds the signal charge transferred from the light receiving unit, and
an output unit that detects the signal charge read out from the signal holding unit;
the output unit is located at one of the vertexes of the pixel; and
the signal holding unit is located between the light receiving unit and the output unit.

2. The imaging device according to claim 1, characterized in that
in a case where the pixel includes any one of
a transfer unit between the light receiving unit and the signal holding unit, and
a reading unit between the signal holding unit and the output unit,
any one of the transfer unit and the reading unit and the signal holding unit are linearly arranged between the light receiving unit and the output unit.

3. The imaging device according to claim 1, characterized in that
in a case where the pixel includes both of
a transfer unit between the light receiving unit and the signal holding unit, and
a reading unit between the signal holding unit and the output unit,
the transfer unit, the signal holding unit, and the reading unit are linearly arranged between the light receiving unit and the output unit.

4. The imaging device according to claim 2, characterized in that
in a case where the pixel includes the transfer unit,
an electrode included in the signal holding unit and an electrode included in the transfer unit are integrated, or
common voltage is applied to the electrode included in the signal holding unit and the electrode of the transfer unit.

5. The imaging device according to claim 3, characterized in that
in a case where the pixel includes the transfer unit,
an electrode included in the signal holding unit and an electrode included in the transfer unit are integrated, or
common voltage is applied to the electrode included in the signal holding unit and the electrode of the transfer unit.

6. The imaging device according to claim 1, characterized in that
in the pixel,
the signal holding unit is configured to use an N type semiconductor layer for signal holding in a MOS type structure including an electrode, an oxide film, and a semiconductor, and
voltage of the electrode unit is zero or negative voltage during a period in which the signal charge is held in the signal holding unit.

7. The imaging device according to claim 1, characterized in that
in the pixel,
a shape of a boundary region between the signal holding unit and the light receiving unit has
an inclination of less than 90 degrees
with respect to a shape of a boundary region
with the pixel adjacent to the pixel.

8. The imaging device according to claim 7, characterized in that
the pixels are arranged in a matrix along two axes intersecting at 90 degrees on an arranged plane.

9. The imaging device according to claim 7, characterized in that the inclination is ±45 degrees.

10. The imaging device according to claim 1, characterized in that
a shape of the pixel having the plurality of vertexes is
rectangular, square, rhombic, trapezoidal, or curved.

11. The imaging device according to claim 1, characterized in that
a shape of a boundary region between the signal holding unit and the light receiving unit is
a partial side of a polygon having an even number of sides,
a partial side of a polygon obtained by rotating the polygon having an even number of sides by an angle of [180 degrees/(the even number)], or
a part of an arc.

12. The imaging device according to claim 11, characterized in that
the shape of a boundary region between the signal holding unit and the light receiving unit is
a shape in which an uneven portion is provided on a side of a part of the polygon, or
a shape in which an uneven portion is provided in the arc.

13. The imaging device according to claim 1, characterized in that the signal holding unit is a polygon having more sides than a quadrangle.

14. The imaging device according to claim 1, characterized in that
A plurality of the pixels is
arranged in a staggered manner.

15. The imaging device according to claim 1, characterized in that
in a plurality of the pixels arranged in a staggered manner,
a pixel in an n-th row of a staggered array and
a pixel in an n+1-th row of the staggered array are
adjacent to each other in an oblique direction with respect to a row direction.

16. The imaging device according to claim 2, characterized in that
A plurality of the pixels is
arranged in a staggered manner.

17. The imaging device according to claim 2, characterized in that
in a plurality of the pixels arranged in a staggered manner,
a pixel in an n-th row of a staggered array and
a pixel in an n+1-th row of the staggered array are
adjacent to each other in an oblique direction with respect to a row direction.

18. The imaging device according to claim 3, characterized in that
A plurality of the pixels is
arranged in a staggered manner.

19. The imaging device according to claim 3, characterized in that
in a plurality of the pixels arranged in a staggered manner,
a pixel in an n-th row of a staggered array and
a pixel in an n+1-th row of the staggered array are
adjacent to each other in an oblique direction with respect to a row direction.

20. The imaging device according to claim 1, characterized in that
in the pixel,
the signal holding units are provided in at least two or more locations.

21. The imaging device according to claim 1, characterized in that
in the pixel,
the output unit is shared by two or more adjacent ones of the pixels.

22. The imaging device according to claim 14, characterized in that
in the pixels,
the output unit is shared by two or more adjacent ones of the pixels.

23. The imaging device according to claim 16, characterized in that
in the pixel,
the output unit is shared by two or more adjacent ones of the pixels.

24. The imaging device according to claim 18, characterized in that
in the pixels,
the output unit is shared by two or more adjacent ones of the pixels.
